(19) United States
(12) Patent Application Publication
(10) Pub. No.: US 2025/0259855 A1
(43) Pub. Date: Aug. 14, 2025

(54) IN-SITU METAL DEPOSITION FOR REDUCED CHARGING DURING DIELECTRIC ETCH

(71) Applicant: Tokyo Electron Limited, Tokyo (JP)

(72) Inventors: Joshua Baillargeon, Albany, NY (US); Alec Dorfner, Albany, NY (US)

(21) Appl. No.: 18/439,469

(22) Filed: Feb. 12, 2024

(51) Int. Cl. H01L 21/311; C23C 16/02; C23C 16/04; C23C 16/06; C23C 16/32; C23C 16/34; C23C 16/50; H01J 37/32; H01L 21/033

(52) U.S. Cl. CPC H01L 21/31144; C23C 16/0245; C23C 16/042; C23C 16/06; C23C 16/32; C23C 16/34; C23C 16/50; H01J 37/32449; H01L 21/0332; H01J 2237/3321; H01J 2237/3341

(57) ABSTRACT

A method of etching a dielectric material (e.g., high aspect ratio etching) includes the following steps, which may be performed as a cycle, in situ within an etching chamber: performing an etch step (e.g., a reactive-ion etching step) that includes etching the dielectric material (e.g., oxide, an ONO stack, thick oxide, etc.) through openings of a mask, which may be a conductive mask, using plasma generated from an etch precursor gas to form recesses in the dielectric material, and performing a deposition step (e.g., a chemical vapor deposition step, such as a plasma-enhanced chemical vapor deposition step) that includes depositing a conductive coating including a metal on both the mask and the dielectric material including sidewalls of the recesses using a deposition gas including the metal.

### TECHNICAL FIELD

The present invention relates generally to etching of dielectric materials, and, in particular embodiments, to systems and methods for etching a dielectric material using a metal-containing conductive coating that is deposited in situ in an etching chamber.

### BACKGROUND

Microelectronic device fabrication typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, with plasma etching processes being an example of a dry etching process. Etching processes to etch dielectric materials are often used to create electrical (e.g., conductive) connections between and within layers. However, because dielectric materials have low electric conductivity, they can accumulate charge during the etching process. This accumulated charge has a negative impact on various aspects of the etch features, such as notching, twisting, trenching, and others.

Etching processes are used in a variety of semiconductor processing areas such as in memory manufacture. One category of etching processes is high aspect ratio (HAR) etching, which includes processes such as high aspect ratio contact (HARC) etches for contact formation. Obtaining a high aspect ratio during etching is important for a variety of semiconductor processes such as during NAND formation (e.g., 3D-NAND), NOR gate formation, and others. One way that manufacturers are using HAR etching processes is to increase the number of transistors and other semiconductor devices per unit area, is utilizing the vertical dimension (3D). For example, in a 3D NAND memory array, charge trapping flash transistors are stacked vertically one on top of another on the sidewalls in high aspect ratio openings. In DRAM memory arrays, to increase capacitance, high aspect ratio DRAM trench capacitor openings are etched deeper and deeper into the semiconductor substrate. Through silicon vias (TSV) for stacking integrated circuit chips are fabricated by etching high aspect ratio holes completely through substrates.

Many of the undesirable effects of charge buildup that can occur during all types of dielectric etches are exacerbated for HAR etching processes. In particular, the increased depth of the etch features relative to the width increases the degree of verticality needed to deliver charged species (e.g., ions) to the bottom of the features. As a consequence, even small deflections caused by the accumulation of charge can have large undesirable effects on the etching process.

Therefore, improved systems and methods for etching dielectric materials that reduce charge buildup during the etching process are desirable.

### SUMMARY

In accordance with an embodiment of the invention, a method of etching a dielectric material includes cyclically performing a cycle that includes the following steps in situ within an etching chamber: performing an etch step that includes etching the dielectric material through openings of a mask using plasma generated from an etch precursor gas to form recesses in the dielectric material, and performing a deposition step that includes depositing a conductive coating including a metal on both the mask and the dielectric material including sidewalls of the recesses using a deposition gas including the metal.

In accordance with another embodiment of the invention, a method of high aspect ratio contact (HARC) etching a wafer within a plasma etching chamber using chemical vapor deposition (CVD) and reactive-ion etching (RIE) includes performing a CVD step on the wafer in situ within the plasma etching chamber. The CVD step includes conformally depositing a conductive coating in openings of a hardmask overlying a dielectric material using a deposition gas including a metal. The conductive coating also includes the metal. The method further includes performing an RIE step on the wafer in situ within the plasma etching chamber. The RIE step includes etching the dielectric material through the openings of the hardmask using plasma generated from an etch precursor gas including an etchant species to extend recesses into the dielectric material. The plasma includes reactive ions of the etchant species.

In accordance with still another embodiment of the invention, a plasma etching system includes a plasma etching chamber, a substrate support disposed in the plasma etching chamber and configured to support a substrate including a dielectric material, an etch precursor gas source fluidically coupled to the plasma etching chamber and configured to supply an etch precursor gas through a first valve, a deposition gas source fluidically coupled to the plasma etching chamber and configured to supply a deposition gas including a metal through a second valve, and a controller operationally coupled to the first valve and the second valve, the controller including a processor and a non-transitory computer-readable medium storing a program including instructions that, when executed by the processor, perform a method. The method includes cyclically performing a cycle including the following steps in situ within the plasma etching chamber: performing an etch step that includes etching the dielectric material through openings of a mask using plasma generated from the etch precursor gas to form recesses in the dielectric material, and performing a deposition step that includes depositing a conductive coating including the metal on both the mask and the dielectric material including sidewalls of the recesses using the deposition gas.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate two example substrates having recesses etched into dielectric material using a mask, where FIG. 1A conceptually depicts adverse impacts of charge build up at sidewalls of the recesses and the mask on the etch profile of the recesses and where FIG. 1B conceptually depicts a configuration with conductive sidewalls that neutralized charge and advantageously improve the etch profile in accordance with embodiments of the invention;

FIGS. 2A, 2B, and 2C illustrate an example etching process including a deposition step and an etch step that are both performed in situ in an etching chamber, the deposition step depositing a conductive coating including a metal on sidewalls of etched recesses, where FIG. 2A shows an optional preliminary etch step, FIG. 2B shows the deposition step, and FIG. 2C shows the etch step in accordance with embodiments of the invention;

FIGS. 3A, 3B, and 3C illustrate an example etching process including a modification step, a deposition step, and an etch step that are all performed in situ in an etching chamber, the modification step forming an intermediate layer at sidewalls of etched recess while the deposition step deposits a conductive coating including a metal on the intermediate layer, where FIG. 3A shows the modification step, FIG. 3B shows the deposition step, and FIG. 3C shows the etch step in accordance with embodiments of the invention;

FIGS. 4A and 4B illustrate another example etching process including a deposition step and an etch step that are both performed in situ in an etching chamber, the deposition step being a reduction reaction, where FIG. 4A shows the reduction reaction and FIG. 4B shows the etch step in accordance with embodiments of the invention;

FIGS. 5A, 5B, and 5C illustrate still another example etching process including a deposition step and an etch step that are both performed in situ in an etching chamber, the deposition step being a replacement reaction, where FIG. 5A shows an optional modification step, FIG. 5B shows the replacement reaction, and FIG. 5C shows the etch step in accordance with embodiments of the invention;

FIG. 6 illustrates a conceptual flowchart of an example etching process including cyclical in situ HARC etch processing that alternates between a metal coating deposition step and a HARC etch step in accordance with embodiments of the invention;

FIG. 7 illustrates an example plasma etching system that includes an etching chamber within which etch processes including a deposition step and an etch step that are both performed in situ in the etching chamber may be performed in accordance with embodiments of the invention;

FIG. 8 illustrates an example method of etching a dielectric material where the method includes cyclically performing a cycle comprising an etch step and a deposition step in situ within an etching chamber in accordance with embodiments of the invention; and

FIG. 9 illustrates an example method of HARC etching a wafer within a plasma etching chamber using chemical vapor deposition (CVD) and reactive-ion etching (RIE) that are both performed in situ within the plasma etching chamber in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Charging effects during dielectric etching processes can cause undesirable etch profile characteristics, diminished etch rate, and reduce the attainable aspect ratio. Additional non-uniformity caused by charge buildup may be introduced due to irregular polymer deposition on feature sidewalls (as well as other factors such as spatial layouts of etched features, features that have already been metalized, etc.), which may localize charge in random areas. Charging effects have been a difficult problem to overcome during dielectric etching processes (such as HAR etching processes), and leads to unwanted phenomenon such as twisting, mouse-bite, contact distortion, and others.

Throughput and process compatibility also remain important when attempting to mitigate the effects of charging. For example, one potential strategy might be to deposit a material that can reduce charge buildup. However, conventional processes require a separate deposition step in a separate tool in order to deposit such a material. Additionally, charge accumulates in the etch features themselves. So, in order to mitigate charge buildup in the etch features, the substrate would have to be removed from the etching chamber at least once (or even several times because the features continue to deepen) further reducing efficiency and adding complexity. And, in some cases, removing the substrate from the etching chamber during the etching process is not possible due to the sensitivity of structures and/or materials on the substrate.

In accordance with various embodiment herein described, the invention proposes a method of etching a dielectric material including a deposition step and an etch step, both performed on the dielectric material in situ within an etching chamber. For example, the deposition step and the etch step may be cyclically performed in situ within the etching chamber. The deposition step includes depositing a conductive coating comprising a metal (e.g., the conductive coating may be a metal, a metal nitride, a metal carbide, metal silicide, etc.) in openings of a mask overlying the dielectric material. In particular, the conductive coating is deposited on sidewalls of recesses (e.g., conformally, on the entire sidewall, or a portion thereof). The etch step includes etching the dielectric material through the openings (e.g., using plasma generated from an etch precursor gas) to form the recesses. For example, when performed cyclically, each deposition step may deposit new conductive material (either adding to existing conductive material or forming an entirely new conductive coating) while each etch step may extend the recesses deeper into the dielectric material.

The method may advantageously alleviate buildup of charge (i.e., charging) during etching of a dielectric material by depositing a metal-containing conductive coating in situ in an etching chamber during the etching process. For example, the metal-containing conductive coating may promote a conductive pathway from the bottom of the recesses (or near the bottom, or some distance into the recesses) to a mask overlying the dielectric material. Conduction electrons in the coating may then redistribute to counteract charge buildup and advantageously reduce ion deflection from charging.

Various systems may be used to perform the embodiment methods. For example, an etching system configured to perform the embodiment methods may include an etching chamber (e.g., a plasma etching chamber), a substrate support disposed in the etching chamber that is configured to support a substrate includes a dielectric material, an etch precursor gas source, a deposition gas source, and a controller. The gas sources may be fluidically coupled to the etching chamber (e.g., using valves that may be adjusted by the controller. The controller includes a processor and a non-transitory computer-readable medium storing a program including instructions that, when executed by the processor, perform the embodiment methods.

Cyclic etching processes that use both etch steps and deposition steps in combination in-situ within an etching chamber are not the conventional approach. Rather, conventional approaches separate etch and deposition, removing the substrate for deposition (e.g., deposited metals via chemical vapor deposition (CVD). One example is the deposition of a tungsten (W) shell on an amorphous carbon layer (ACL) hardmask in a separate chamber after openings in the ACL hardmask have been formed (a mask open step), but before transferring the wafer to an etching chamber for an etch step. Additionally, the W shell does not address the charging issue because there is no metal deposited on the sidewalls of features etched into the dielectric layer.

The deposition of a metal-containing conductive coating of features (such as high aspect ratio (HAR) features) during the etching process (e.g., continuously as part of an in situ cycle within an etching chamber) may have the benefit of reducing or eliminating the ability of charging effects to hinder the etch front. For example, there may be a higher ion flux reaching bottom regions of the features (e.g., trenches, holes, etc.) that have a conductive coating compared to coatings with a dielectric (or insulating) surface. This may indicate less sidewall charging (because charge buildup deflects and repels ions that may otherwise enter the openings so increased flux suggests less accumulated charge).

The metal-containing conductive coating (e.g., a metal hardmask (MHM) coating) may have other advantages in addition to improved charging characteristics. For example, the metal-containing conductive coating may also provide improved selectivity over the bare mask. Etch profile advantages may also be realized using a metal-containing conductive coating (that may be continually refreshed as part of an in situ cycle), whether through improved charge dissipation or through other properties of the coating, such as reducing mouse-bite, distortion, twisting, bowing, etc.

A possible further advantage of the proposed method is that it is compatible with existing processing tools. For example, a number of etch precursor gases and deposition gases that are usable in the described methods are used in existing processing systems (although not in the same way). Additionally, existing tools such as plasma etching tools may be adapted to perform the described processes without overly complicated or expensive modifications. This also applies to tools that may be used before or after the described methods (such as to form or removed the mask and/or metal-containing conductive coating).

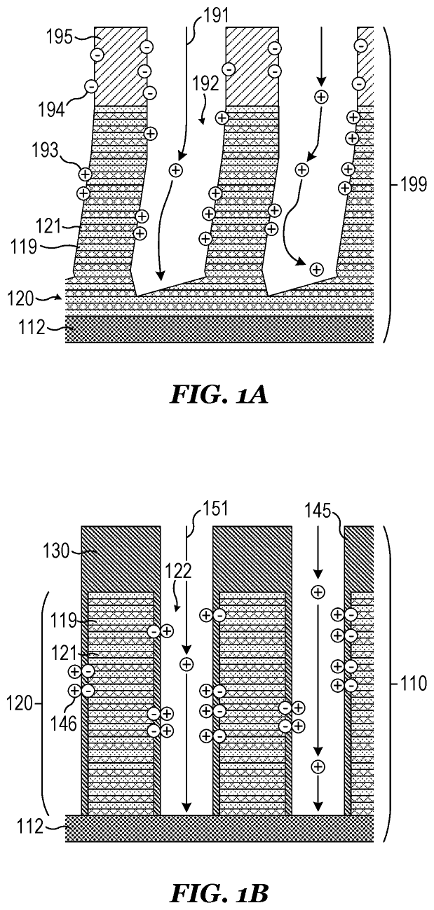

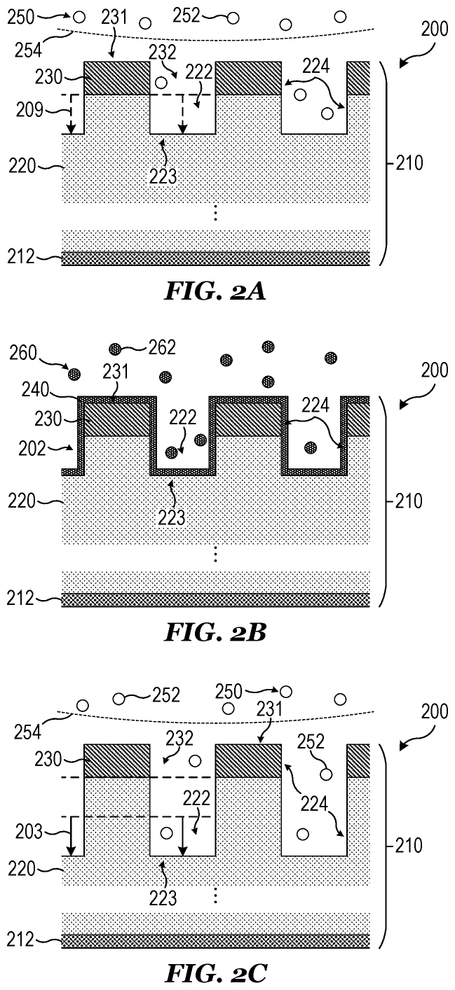

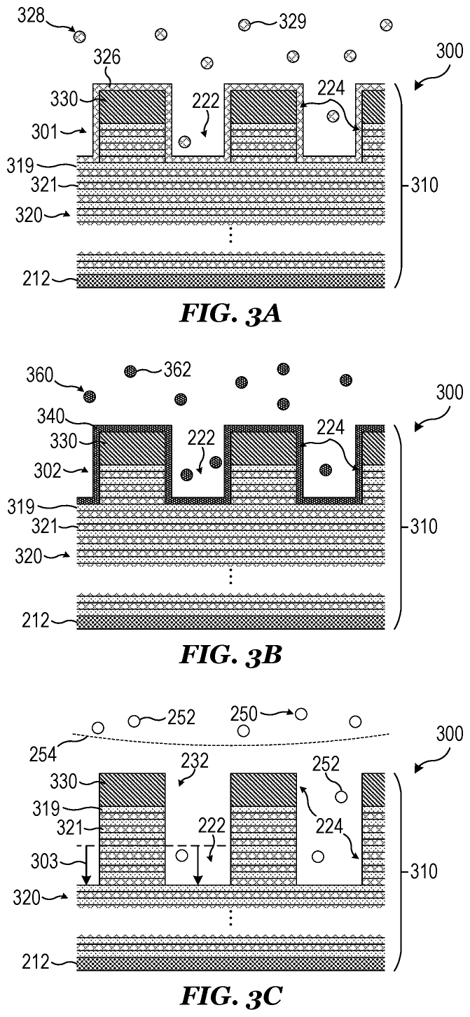

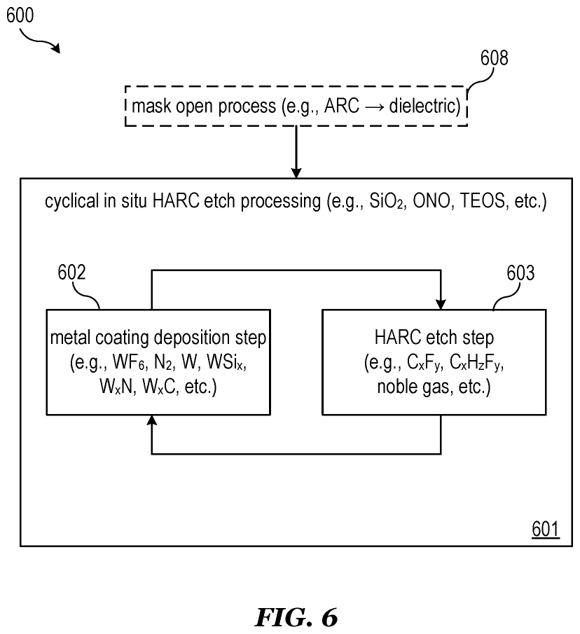

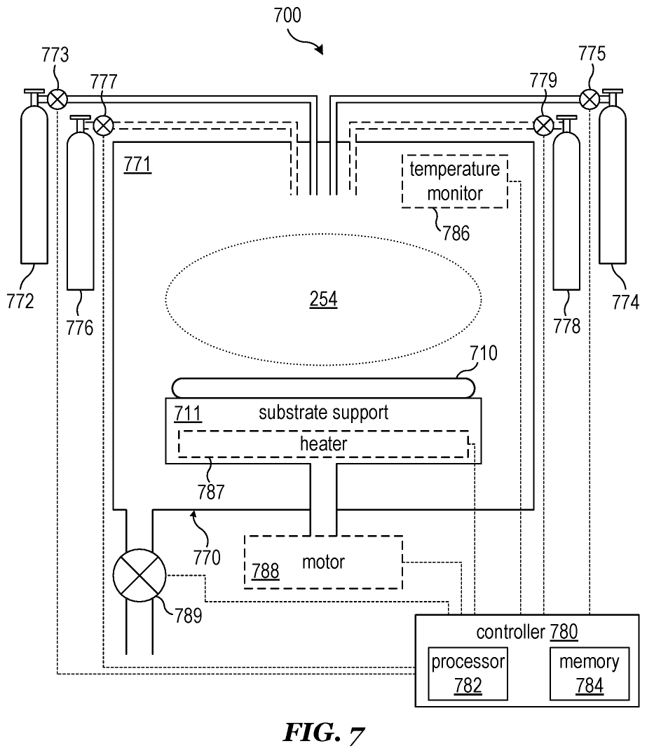

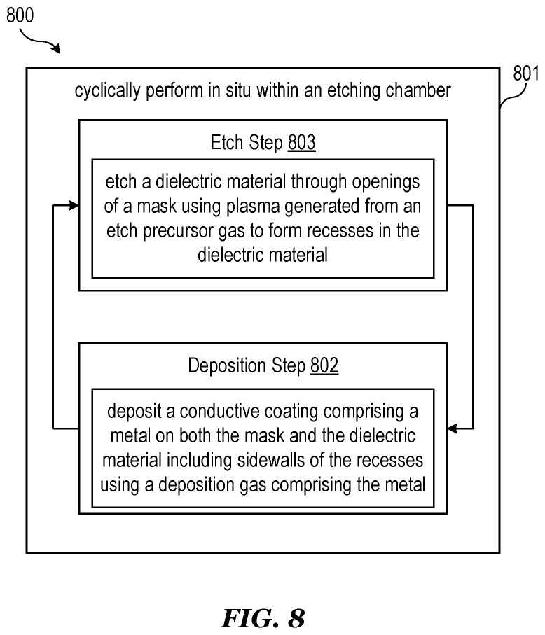

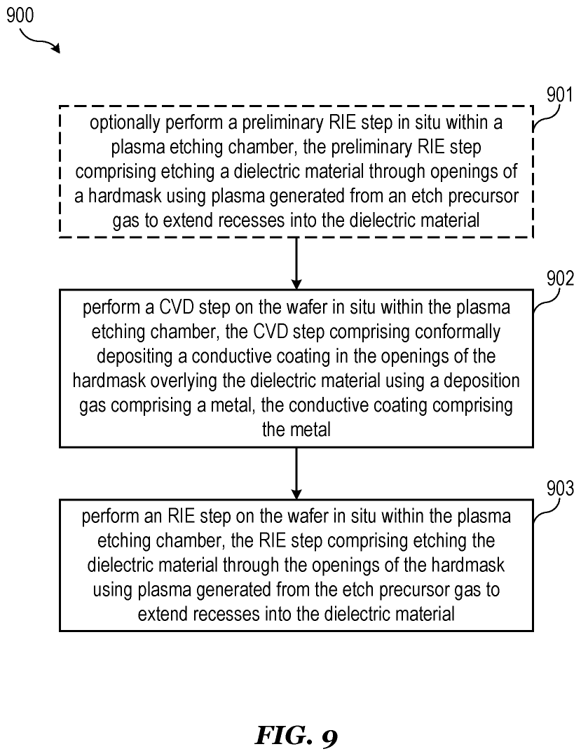

Embodiments provided below describe various methods and systems for etching of dielectric materials, and in particular embodiments, to methods and systems for etching a dielectric material using a metal-containing conductive coating that is deposited in situ in an etching chamber. The following description describes the embodiments. FIGS. 1A and 1B are used to describe example etch profiles with and without alleviating charging during the etching process. An example etching process is described using FIGS. 2A-2C. Three more example etching process are described using FIGS. 3A-5C. FIG. 6 is used to describe a conceptual flow chart of an etching process. An example plasma etching system is described using FIG. 7 while two example methods of etching a dielectric material are described using FIGS. 8 and 9.

FIGS. 1A and 1B illustrate two example substrates having recesses etched into dielectric material using a mask, where FIG. 1A conceptually depicts adverse impacts of charge build up at sidewalls of the recesses and the mask on the etch profile of the recesses and where FIG. 1B conceptually depicts a configuration with conductive sidewalls that neutralized charge and advantageously improve the etch profile in accordance with embodiments of the invention.

Referring to FIG. 1A, a substrate 199 includes a dielectric material 120 disposed over an underlying layer 112. The dielectric material 120 may include multiple layers, such as oxide layers 119 separated by nitride layers 121 (i.e., an ONO stack), as shown in the specific example of the substrate 199. A mask 195 is disposed over the dielectric material 120 and is configured to facilitate transfer of a pattern into the dielectric material 120 via an etching process. For example, ions may be directed towards the substrate 199 during the etching process to etch the dielectric material 120 through the mask 195.

In the specific example of the substrate 199, charges (illustrated conceptually as positive charges 193 and negative charges 194) build up on surfaces of the mask 195 and the dielectric material 120 during the etching process (so-called charging effects). Because the mask 195 and the dielectric material 120 are not electrically conductive, there can be insufficient available charge (such as free electrons or other charges with sufficient mobility) to locally neutralize the charge buildup. This can influence the verticality of ions during the etching process undesirably resulting in deflected ion paths 191 that alter the etch profile (such as by forming twisting recesses 192, but other problematic etch profiles may also result, such as trenching, notching, etc.).

Referring now to FIG. 1B, the substrate 199 is contrasted with a substrate 110 that includes a conductive material 145 disposed over surfaces of the dielectric material 120 and the mask 130 (or the conductive material 145 may be the same material as the mask 130 as conceptually shown here). That is, the conductive material 145 is on at least sidewalls of recesses 122 in the dielectric material 120 that are formed during the etching process and may also cover or otherwise be part of the mask 130.

In comparison to the situation of FIG. 1A where the negative charges 194 and the positive charges 193 remain on the mask 195 and sidewalls of the dielectric material 120 (i.e., the twisting recesses 192), the conductive material 145 shown in FIG. 1B allows free electrons (or other mobile charge) to rearrange and neutralize charges that build up on surfaces of the dielectric material 120 and the mask 130 (shown as neutralized charges 146). The neutralized charges 146 may have the advantage of having little or no impact on the trajectory of ions used to etch the dielectric material 120 resulting in vertical ion paths 151 (or substantially vertical) forming improved etch profiles.

FIGS. 2A, 2B, and 2C illustrate an example etching process including a deposition step and an etch step that are both performed in situ in an etching chamber, the deposition step depositing a conductive coating including a metal on sidewalls of etched recesses, where FIG. 2A shows an optional preliminary etch step, FIG. 2B shows the deposition step, and FIG. 2C shows the etch step in accordance with embodiments of the invention.

Referring to FIG. 2A, an etching process 200 may begin with an optional preliminary etch step 209 during which a dielectric material 220 is etched through openings 232 in a mask 230 to form recesses 222 extending from a top surface 231 of the mask 230 to bottom surfaces 223 within the dielectric material 220. As schematically illustrated, a substrate 210 includes the dielectric material 220 disposed on an underlying layer 212 (or layers). A plasma 254 may be generated from an etch precursor gas 250 and used to etch the dielectric material 220 forming the recesses 222. One or more species within the etch precursor gas 250 may act as etchant species 252 (e.g., generated by the plasma 254), and interact (react chemically, impact ballistically, etc.) with the dielectric material 220 to remove material from the openings 232 of the mask 230.

It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

The etching process 200 may be any suitable type of etching process, and is a plasma etching process in various embodiments (such as the specific example shown here). In one embodiment, the optional preliminary etch step 209 is a reactive-ion etching (RIE) process. Moreover, the etching process 200 may be a HAR (high aspect ratio) etching process, such as a HARC etching process. For example, the etching process 200 may be well-suited for HAR etching processes because of the benefits to ion verticality and etch profile afforded by the reduced effects of charging. In various embodiments, the etching process 200 is a cyclic process that is performed by repeating a cycle that includes two or more steps until the desired etch endpoint (e.g., depth, layer, etc.) is reached.

When the optional preliminary etch step 209 is a plasma etching process, various types of plasma may be used. For example, the plasma 254 may be a capacitively-coupled plasma (CCP), inductively-coupled plasma (ICP), surface wave plasma (SWP), wave-heated plasma, and the like. Similarly, various materials or combinations of materials (e.g., gases) may be used as the etchant species 252, such as ions of argon (Ar), or other inert ions such as krypton (Kr), fluorocarbons (CₓF_{y}), hydrofluorocarbons (CₓH_{z}F_{y}), and others. In some cases, it may be advantageous to select the etch precursor gas 250 (and the etching process 200 as a whole) to utilize oxygen-free chemistry, such as to prevent oxidation of deposited conductive coatings (the metals in the conductive coatings, for example).

The substrate 210 may be any suitable substrate, such as an insulating, conducting, or semiconducting substrate with one or more layers disposed thereon. For example, the underlying layer 212 of the substrate 210 may be a semiconductor wafer, such as a silicon wafer, and include various layers, structures, and devices (e.g., forming integrated circuits). In one embodiment, the underlying layer 212 includes silicon. In another embodiment, the underlying layer 212 includes silicon germanium (SiGe). In still another embodiment, the underlying layer 212 includes gallium arsenide (GaAs). Of course, many other suitable materials, semiconductor or otherwise, may be included in the underlying layer 212 as may be apparent to those of skill in the art.

The dielectric material 120 may be any suitable material or combination of materials that behaves as an electrical dielectric in the context of a given application (relative to materials behaving as semiconductors or conductors, for example). In various embodiments, the dielectric material 120 includes an oxide material (e.g., thick oxide), and the dielectric material 120 includes silicon dioxide (SiO₂) in one embodiment, and includes tetraethyl orthosilicate (TEOS) in one embodiment. In some embodiments, the dielectric material 120 includes a nitride material, and the dielectric material 120 includes silicon nitride (Si₃N₄) in one embodiment. Of course, other classes of dielectric material may also be included in the dielectric material 120, such as an oxynitride material (e.g., silicon oxynitride (SiOₓN_{y}), and others).

The dielectric material 120 may include more than one type of material (even including materials not necessarily acting as or classified as dielectric materials so long as portions of the dielectric material 120 near the surface are prone to charge buildup). In some specific applications, such as HARC etches, the dielectric material 120 may be a stack of several layers of dielectric material. One specific example is an ONO stack, which includes a multiple oxide layers (e.g., SiO₂) separated by nitride layers (e.g., Si₃N₄).

The mask 230 may be any suitable mask that is configured to protect regions of the dielectric material 120 while allowing the dielectric material 120 to be etched through the openings 232 during the etching process 200. In various embodiments, the mask 230 is a hardmask. The mask 230 may be electrically conductive, semiconducting, or insulating. In some embodiments, the mask 230 is a conductive mask, such as a metal hardmask (MHM). In one embodiment, the mask 230 is an ACL mask, which may have moderate conductivity relative to an MHM, for example. In another embodiment, the mask 230 is tungsten silicide (WSiₓ), which may also be considered an MHM. Of course, many other mask materials may be used.

The recesses 222 may have any shape or combination of shapes, although the desired shapes may depend on the specific requirements of a given application. Some broad categories of shapes that the recesses 222 may have are holes (which may be thought of as zero-dimensional objects in a pattern), lines (which may be thought of as one-dimensional objects in a pattern), and trenches (which may refer to various elongated objects in the pattern including, but not limited to, lines). As the recesses 222 are etched into the dielectric material 120, the bottom surfaces 223 recede forming sidewalls 224 of the recesses 222. The openings 232 also define part of the sidewalls 224, the recesses 222 being formed according to the positions of the openings 232.

Now referring to FIG. 2B, the etching process 200 includes a deposition step 202 to form (e.g., deposit) a conductive coating 240 on at least the sidewalls 224 of the recesses 222. In various embodiments, the conductive coating 240 is deposited conformally on all (or most) of the exposed surfaces of the mask 230 and the dielectric material 220 (i.e., the sidewalls 224 of both the recesses 222 and the openings 232 and the bottom surfaces 223 of the recesses 222 as well as the top surface 231 of the mask 230). The optional preliminary etch step 209 may be included as the first step of the etching process 200 to form initial recesses before the effects of charging become significant. Alternatively, the deposition step 202 may be the first step of the etching process 200.

A deposition gas 260 that includes a metal 262 is used to form the conductive coating 240 during the deposition step 202. For example, the deposition gas 260 may include one or more compounds that includes the metal 262 and interact (e.g., react) with surfaces of the dielectric material 220 and/or the mask 230 to form the conductive coating 240. The deposition gas 260 may include more than one type of gas and a variety of gases may be used. For example, in addition to a gas including the metal, the deposition gas 260 may also include other gases which may participate or otherwise facilitate the deposition of the conductive coating 240, such as hydrogen (H₂), nitrogen (N₂), and others. Inert (or at least unreactive in the context of the given application) gases may also be included, and may be referred to as carrier gases. One category of gases that may be used as carrier gases are noble gases, such as argon (Ar), helium (He), krypton (Kr), and the like.

One category of gases which may be used as a component of the deposition gas 260 is a metal halide gas. For example, the deposition gas 260 may include a compound that is some combination of a metal (e.g., tungsten (W), tantalum (Ta), molybdenum (Mo), titanium (Ti), Ruthenium (Ru), etc.) and a halide (e.g., fluorine (F), chlorine (Cl), bromine (Br), etc.). In various embodiments, the metal is tungsten and the deposition gas 260 includes tungsten fluoride (WF₆) in one embodiment, and include tungsten chloride (WCl₆) in one embodiment.

Although many deposition techniques may be used, in various embodiments, the deposition step 202 includes a conformal deposition technique, such as CVD (chemical vapor deposition), atomic layer deposition (ALD), molecular layer deposition (MLD), and others. Moreover, the chemistry of the deposition techniques may vary, such as including reduction reactions, replacement reactions, and others. In one embodiment, the deposition step 202 is a plasma-enhanced CVD (PE-CVD) technique, which may have the particular advantage that the etching process 200 may already be performed in a plasma etching chamber (e.g., because the etch steps also utilize plasma). When the deposition step 202 is a PE-CVD technique some of the components of the deposition gas 260 may form a plasma (e.g., argon, helium, etc.). In some alternative embodiments, solid deposition sources may even be used (such as in physical vapor deposition (PVD) techniques), particularly if techniques are used to deposit the conductive coating 240 of the sidewalls 224, such as through angled deposition techniques.

Turning now to FIG. 2C, the etching process 200 also includes an etch step 203 during which the recesses 222 are extended deeper into the dielectric material 220. The conductive coating 240 may advantageously dissipate and/or neutralize charge buildup during the etch step 203. The etch step 203 may be similar to or identical to the optional preliminary etch step 209 when it is included, but this is not required. During the etch step 203 some or all of the conductive coating 240 may be etched away (as conceptually illustrated). The deposition step 202 and the etch step 203 may be repeated (e.g., alternated) as a cycle in situ within the etching chamber until the desired endpoint is met (e.g., reaching the underlying layer 212, reaching a certain depth within the dielectric material 220, etc.).

Practically speaking, the duration of each step may depend on the need to deposit additional conductive coating 240 in a subsequent deposition step 202 to prevent undesirable etch defects. As examples, the deposition step 202 may be on the order of seconds while the etch step 203 may be on the order of minutes. Additional steps (phases) may be included within or between the deposition step 202 and the etch step 203, such as settling steps allowing the environment of the etching chamber to sufficiently equilibrate before commencing the next step (e.g., to allow both the removal of gases and byproducts from a previous step and the introduction of new gases). Additionally, modification steps may also be performed in situ within the etching chamber, such as to prepare surfaces for the formation of the conductive coating 240 during the deposition step 202.

FIGS. 3A, 3B, and 3C illustrate an example etching process including a modification step, a deposition step, and an etch step that are all performed in situ in an etching chamber, the modification step forming an intermediate layer at sidewalls of etched recess while the deposition step deposits a conductive coating including a metal on the intermediate layer, where FIG. 3A shows the modification step, FIG. 3B shows the deposition step, and FIG. 3C shows the etch step in accordance with embodiments of the invention. The etching process of FIGS. 3A-3C may be a specific implementation of other etching processes described herein such as the etching process of FIGS. 2A-2C, for example. Similarly labeled elements may be as previously described.

Referring to FIGS. 3A-3C, an etching process 300 includes a modification step 301 during which an intermediate layer 326 is formed before forming a conductive coating 340 using a deposition gas 360 including a metal 362 in a deposition step 302 followed by an etch step 303. For example, the intermediate layer 326 may be formed conformally over a dielectric material 320 and a mask 330. The intermediate layer 326 is formed over the dielectric material 320 and covers the sidewalls 224 (e.g., of the recesses 222, and also potentially sidewalls and the top surface of the mask 330), as shown. As before, the etching process 300 may be a cyclical process that repeats a cycle including the modification step 301, the deposition step 302, and the etch step 303.

The intermediate layer 326 may be formed using a modification gas 328 that includes an intermediate material 329. The intermediate layer 326 may be formed for various reasons, including enhancing adhesion of the conductive coating 340 to surfaces of the dielectric material 320 and the mask 330, serving as a seed material for the deposition process, modifying the material composition of the conductive coating 340, and others. In one specific example, the modification step 301 is a nitrogen treatment (e.g., using nitrogen gas (N₂), ammonia (NH₃) as a plasma treatment, thermal treatment, or combination thereof) to form a nitrogen-containing layer (e.g., nitride). In another example, the modification step 301 is a silane treatment (using silane (SiH₄), chlorosilane (SiCl₄), etc.) to form a silicon-containing layer. Alternatively, the modification step 301 may simply modify surfaces, such as a surface activation step, the activated surface being considered the intermediate layer 326 (i.e. the activated surface may have different terminal species, different charge, different oxidation state, etc. than before).

Using an intermediate layer may have the advantage of promoting uniformity (e.g., thickness, continuity, and/or composition) of the conductive coating 340. For example, in the specific example illustrated, a substrate 310 includes the dielectric material 320 implemented as an ONO stack (including oxide layers 319 separated by nitride layers 321). The conductive coating 340 may not deposit equally on different materials used in the dielectric material 320, such as the oxide layers 319 and the nitride layers 321 of the dielectric material 320. In particular, some metals, such as tungsten, may not deposit on an oxide, such as silicon dioxide, but may deposit on a nitride, such as silicon nitride. In these cases, an ONO stack may cause a non-uniform conductive coating 340 leading to etching defects (e.g., striations) in the dielectric material 320. However, a nitride-containing intermediate layer (e.g., SiON) may provide the benefit of improving the uniformity of the conductive coating 340.

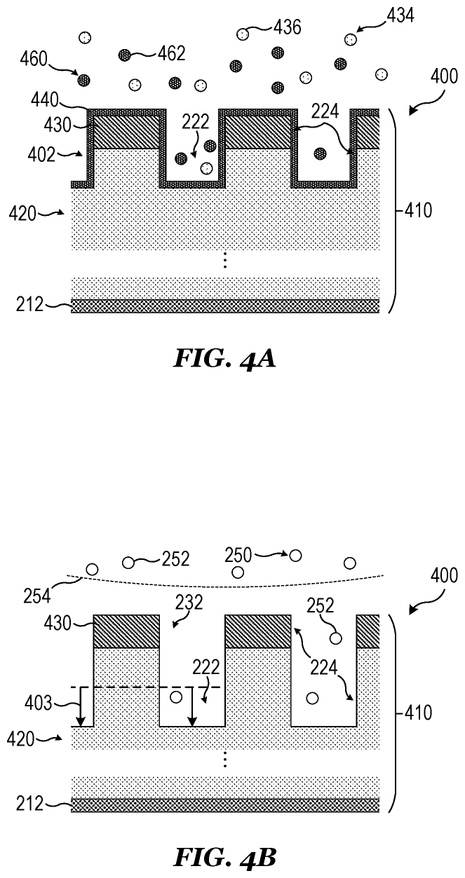

FIGS. 4A and 4B illustrate another example etching process including a deposition step and an etch step that are both performed in situ in an etching chamber, the deposition step being a reduction reaction, where FIG. 4A shows the reduction reaction and FIG. 4B shows the etch step in accordance with embodiments of the invention. The etching process of FIGS. 4A and 4B may be a specific implementation of other etching processes described herein such as the etching process of FIGS. 2A-2C, for example. Similarly labeled elements may be as previously described.

Referring to FIGS. 4A and 4B, an etching process 400 includes a reduction reaction 402 (i.e., a specific implementation of a deposition step where the oxidation state of a metal 462 included in a deposition gas 460 is reduced during the formation of a conductive coating 440) followed by an etch step 403. The reduction reaction may take place entirely at surfaces (e.g., between the deposition gas 460 and a solid, such as a dielectric material 420 and a mask 430 of a substrate 410), or a reductant gas 434 including a reductant material 436 may be included. In various embodiments, the reduction reaction 402 involves a plasma which may be advantageously generated in the plasma etching chamber used for the etch step 403.

One type of a reduction reaction 402 uses a nitrogen-containing gas in the reductant gas 434, (e.g., N₂) and uses a metal halide (e.g., tungsten fluoride) as the deposition gas 460. In this case, the nitrogen facilitates the reduction reaction 402 to reduce the oxidation number of the metal and deposit a metal nitride as the conductive coating 440. Other gases may also be included. As a specific example, the reaction may be 4WF₆(g)+N₂(g)+12H₂(g)→2W₂N(s)+24HF(g) where tungsten fluoride gas reacts with nitrogen gas and hydrogen gas to form solid tungsten nitride and hydrogen fluoride gas.

Another type of reduction reaction 402 uses a carbon-containing gas in the reductant gas 434, (e.g., methane) and uses a metal halide (e.g., tungsten fluoride) as the deposition gas 460. In analogy to the nitride reduction reaction above, the carbon facilitates the reduction reaction 402 to reduce the metal and deposit a metal carbide as the conductive coating 440. As a specific example, the reaction may be 2WF₆(g)+CH₄(g)+4H₂(g)→W₂C(s)+12HF(g)) where tungsten fluoride gas reacts with methane gas to form solid tungsten carbide and hydrogen fluoride gas.

Many other reduction reactions are also thermodynamically viable, whether at room temperature or at any other desired reaction temperature that is compatible with a given etching process 400. For example, a negative Gibbs free energy (−ΔG) of a given reaction including a metal may indicate potential viability for the formation of a conductive coating including the metal.

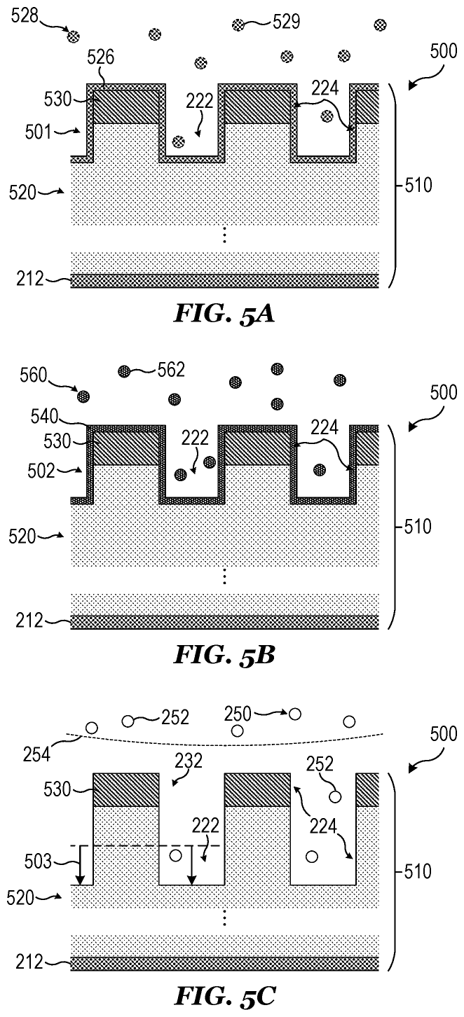

FIGS. 5A, 5B, and 5C illustrate still another example etching process including a deposition step and an etch step that are both performed in situ in an etching chamber, the deposition step being a replacement reaction, where FIG. 5A shows an optional modification step, FIG. 5B shows the replacement reaction, and FIG. 5C shows the etch step in accordance with embodiments of the invention. The etching process of FIGS. 5A-5C may be a specific implementation of other etching processes described herein such as the etching process of FIGS. 2A-2C, for example. Similarly labeled elements may be as previously described.

Referring to FIGS. 5A-5C, an etching process 500 includes an optional modification step 501, a replacement reaction 502 (i.e., a specific implementation of a deposition step where a seed material 529, such as from an optional modification gas 528, is replaced by a metal 562 of a deposition gas 560 to deposit a conductive coating 540). For example, the optional modification step 501 may be used to deposit a seed layer 526 (e.g., an intermediate layer) which is then replaced by the metal of the replacement reaction 502. Alternatively, the replacement reaction 502 may replace a component already existing in a dielectric material 520 and/or a mask 530 included in a substrate 510. In some cases, the replacement reaction 502 may be a type of reduction reaction. In other cases, a reduction reaction may also be included in the etching process 500 along with the replacement reaction 502.

One type of replacement reaction 502 is a replacement reaction of silicon (silicon, such as amorphous silicon (a-Si)) with the metal 562 (e.g., tungsten) contained in the deposition gas 560 (e.g., WF₆). As a specific example, the reaction may be 2WF₆(g)+3Si(s)→2W(s)+3SiF₄(g). In some cases, additional energy may be needed (such as thermal energy, plasma energy as in in a plasma enhanced conversion process, or a combination thereof). As an example, plasma enhancement in combination with thermal energy may be used when there are limitations on the maximum temperature that can the applied (whether because of technology limitations or thermal budgets of the substrate). For example, the above reaction may have a ΔG of −179.4 kcal/mol at 600 K (and therefore be thermodynamically viable), but ΔG may move toward zero as the temperature decreases reducing the reaction efficiency and eventually making it non-viable.

FIG. 6 illustrates a conceptual flowchart of an example etching process including cyclical in situ HARC etch processing that alternates between a metal coating deposition step and a HARC etch step in accordance with embodiments of the invention. The etching process of FIG. 6 may be a specific implementation of other etching processes described herein such as the etching process of FIGS. 2A-2C, for example. Similarly labeled elements may be as previously described.

Referring to FIG. 6, a conceptual flowchart 600 of an etching process includes cyclical in situ HARC etch processing 601. The cyclical in situ HARC etch processing 601 alternates between a metal coating deposition step 602 and a HARC etch step 603. An optional mask open process 608 may also be considered part of the etching process, for example when a photoresist layer is used as a preliminary mask to form openings in the HARC etch mask (e.g., a hardmask such as an ACL mask, a WSiₓ mask, etc.). Other layers may also be included between the photoresist layer and the HARC etch mask (or may be considered part of the HARC etch mask), such as an antireflective coating (ARC, such as utilizing silicon (SiARC)), an organic planarization layer (OPL), a silicon oxynitride (SiOₓN_{y}) layer, and others. These layers may also be opened during the optional mask open process 608 whether through development or etching.

A metal coating is deposited on the HARC etch mask and an underlying dielectric material (such as an ONO stack, SiO₂, even materials that may act as precursors, such as TEOS, Si₃N₄, etc.) during the metal coating deposition step 602 of the cyclical in situ HARC etch processing 601. Various gases may be provided during the metal coating deposition step 602, such as metal halides, nitrogen, hydrocarbons, hydrogen, and others. The metal coating may be an elemental coating such as a tungsten coating, may be a metallic coating that includes other elements, such as a tungsten silicide (WSiₓ) coating, or may be an electrically conductive material including a metal such as a metal nitride or a metal carbide.

HAR (high aspect ratio) recesses (which will be used for contacts) are etched into the dielectric material during the HARC etch step 603 of the cyclical in situ HARC etch processing 601. Various gases may be provided during the HARC etch step 603, fluorocarbons, hydrofluorocarbons, noble gases such as argon, helium, and krypton, and gases such as N₂, O₂, CO, and others.

FIG. 7 illustrates an example plasma etching system that includes an etching chamber within which etch processes including a deposition step and an etch step that are both performed in situ in the etching chamber may be performed in accordance with embodiments of the invention. The plasma etching system of FIG. 7 may be used to perform any of the example etching processes described herein such as the etching process of FIGS. 2A-2C, for example. Similarly labeled elements may be as previously described.

Referring to FIG. 7, a plasma etching system 700 includes a substrate support 711 disposed within an etching chamber 771 and configured to support a substrate 710. An etch precursor gas source 772 and a deposition gas source 774 are fluidically coupled to the etching chamber 771 through an etch precursor valve 773 and a deposition valve 775 respectively. Additional gas sources and valves may also be included in the plasma etching system 700. For example, an optional additional gas source 776 may be fluidically coupled to the etching chamber 771 through an optional additional gas valve 777 (an additional gas may be any type of gas, such as modification gases, reductant gases, additives, etc. and multiple additional gases may be included) while an optional carrier gas source 778 may be fluidically coupled to the etching chamber 771 through an optional carrier gas valve 779. An exhaust valve 789 is included to evacuate the etching chamber 771 during the etching process.

The plasma etching system 700 is configured to generate a plasma 254 during any or all of the steps of an etching process, such as the deposition step and/or the etch step of each cycle of the etching process. The etching chamber 771 may be any suitable etching chamber, such as CCP etching chamber, an ICP etching chamber, etc. An optional temperature monitor 786 may be included to monitor and/or aid in controlling the temperature of the substrate 710 and the environment in the etching chamber 771. An optional heater 787 may be included to elevated the temperate of the substrate 710 above the equilibrium temperature at the substrate 710 during the etching process. An optional motor 788 may also be included to improve etching and deposition uniformity.

A controller 780 is operationally coupled to the valves (the etch precursor valve 773, the deposition valve 775, the optional additional gas valve 777, the optional carrier gas valve 779), and may be operationally coupled to any of the optional temperature monitor 786, optional heater 787, optional motor 788, and the exhaust valve 789. The controller 780 includes a processor 782 and a memory 784 (i.e., a non-transitory computer-readable medium) that stores a program including instructions that, when executed by the processor 782, perform an etching process. For example, the memory 784 may have volatile memory (e.g., random access memory (RAM)) and non-volatile memory (e.g., flash memory). Alternatively, the program may be stored in physical memory at a remote location, such as in cloud storage. The processor 782 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 8 illustrates an example method of etching a dielectric material where the method includes cyclically performing a cycle comprising an etch step and a deposition step in situ within an etching chamber in accordance with embodiments of the invention. The method of FIG. 8 may be combined with other methods and performed using the systems and apparatuses as described herein. For example, the method of FIG. 8 may be combined with any of the embodiments of FIGS. 1-7 and 9. Although shown in a logical order, the arrangement and numbering of the steps of FIG. 8 are not intended to be limited. The method steps of FIG. 8 may be performed in any suitable order or concurrently with one another as may be apparent to a person of skill in the art.

Referring to FIG. 8, a method 800 of etching a dielectric material includes a cycle 801 including cyclically performing an etch step 803 and a deposition step 802. In some cases, the deposition step 802 may be performed first while in other cases the etch step 803 may be performed first (e.g., as a preliminary etch step, as previously discussed). The etch step 803 includes etching the dielectric material through openings of a mask using plasma generated from an etch precursor gas. Etching the dielectric material forms recesses (e.g., creates new recesses, or extends existing recesses, which may also be viewed as creating new recesses) in the dielectric material. The deposition step 802 includes depositing a conductive coating comprising a metal on both the mask and the dielectric material using a deposition gas comprising the metal. In particular, the conductive coating is deposited on sidewalls of the recesses (e.g., conformally, or even specifically, the conductive coating forming an electrically conductive pathway along at least a portion of the sidewalls).

The cycle may further include performing a modification step that includes forming an intermediate layer at the sidewalls of the recesses after the etch step 803 and before the deposition step 802. In this case, the deposition step 802 may include depositing the conductive coating on the intermediate layer. The intermediate layer may include nitrogen, for example. Forming the intermediate layer during the modification step may then include treating the sidewalls of the dielectric layer with the nitrogen to form the intermediate layer, but of course other modification steps are possible.

Depositing the conductive coating during the deposition step 802 may include a reduction reaction that reduces the oxidation state of the metal in the deposition gas to deposit the conductive coating. For example, the metal may be part of a compound included in the deposition gas and a reductant may also be included so that the oxidation state of the metal is reduced causing the metal to be part of a different compound deposited as the conductive coating. Additionally, the etch step 803 may specifically be chosen to use oxygen-free chemistry, which may advantageously help to prevent oxidation of the conductive coating.

Alternatively or additionally, depositing the conductive coating during the deposition step 802 may include a replacement reaction between a seed material at the sidewalls of the recesses and the metal of the deposition gas. For example, the seed material may include silicon, and the metal (e.g., tungsten) may then replace the silicon at the sidewalls forming the conductive coating. The seed material may be part of a compound or may be an elemental material in various forms (e.g., in the case of silicon, amorphous silicon, polycrystalline silicon, crystalline silicon, etc.).

In implementations of the method 800 that include a replacement reaction as part of the deposition step 802, the cycle may further include performing a modification step that includes performing a silane treatment to incorporate silicon at the sidewalls of the recesses after the etch step and before the deposition step. The replacement reaction replaces the silicon at the sidewalls of the recesses with the metal of the deposition gas. Various types of silane treatments may be used, such as treating the sidewalls of the recesses with silane (SiH₄), treating the sidewalls of the recesses with chlorosilane (SiCl₄), and others. Additionally, other gases may be included in addition to the silane material, such as to facilitate silane reduction.

While placement and extent of the deposition of the conductive coating may vary between implementations and may even vary within the cycle (e.g., as the recesses become deeper, etc.) it may be desirable to deposit the conductive coating on most of all of the sidewalls of the recesses. For example, in some cases, depositing the conductive coating during the deposition step 802 includes depositing the conductive coating on sidewalls of the mask and the sidewalls of the recesses so that the conductive coating extends from a top surface of the mask substantially to bottom surfaces of the recesses. It should be understood that the substantially language is meant to incorporate such inconsistencies which may occur such as statistical variation between recesses, differences in the depth reached by the conductive layer as the recesses become deeper, as well as being substantially at the bottom surfaces (e.g., within 10% of the height of the recesses).

Any suitable mask may be used, such as a hardmask. In some embodiments, the mask is a conductive mask (e.g., tungsten silicide (WSi), and other tungsten-based masks, such as WSi, WSiN, WC, WB, WBN, as well as similar metal-containing masks that replace tungsten with another metal). Other materials with varying degrees of electrical conductivity may also be used for the mask, such as ACL (amorphous carbon layer), which has some electrical conductivity, or a dielectric mask (e.g., when the conductive coating deposits on sidewalls and/or the top surface of the mask. Similarly, the dielectric material may include any suitable dielectric, such as an oxide (e.g., thick oxide) and/or a nitride. In some implementations, the dielectric material includes multiple dielectric materials, such as when the dielectric material is an ONO stack (i.e., a plurality of oxide layers separated by nitride layers). In one embodiment, the oxide is silicon dioxide (SiO₂). In another embodiment, the oxide is tetraethyl orthosilicate (TEOS).

The conductive coating may also take a variety of material forms. For example, the conductive coating may be a metal coating, a metal nitride coating, a metal carbide coating, and others. In one specific example of a metal nitride coating, the conductive coating is tungsten nitride. For example, to deposit the tungsten nitride coating, the deposition gas may include tungsten, and depositing the conductive coating during the deposition step 802 may include a reduction reaction that reduces the oxidation state of the tungsten in the deposition gas using a nitrogen-containing gas to deposit the tungsten nitride. Similarly, in one specific example of a metal carbide coating, the conductive coating is tungsten carbide. The deposition gas may then include tungsten, and depositing the conductive coating during the deposition step may include a reduction reaction that reduces the oxidation state of the tungsten in the deposition gas using a carbon-containing gas to deposit the tungsten carbide.

FIG. 9 illustrates an example method of HARC etching a wafer within a plasma etching chamber using CVD and RIE that are both performed in situ within the plasma etching chamber in accordance with embodiments of the invention. The method of FIG. 9 may be combined with other methods and performed using the systems and apparatuses as described herein. For example, the method of FIG. 9 may be combined with any of the embodiments of FIGS. 1-8. Although shown in a logical order, the arrangement and numbering of the steps of FIG. 9 are not intended to be limited. The method steps of FIG. 9 may be performed in any suitable order or concurrently with one another as may be apparent to a person of skill in the art.

Referring to FIG. 9, a method 900 of HARC etching a wafer within a plasma etching chamber using CVD and RIE includes performing a CVD step 902 and an RIE step 903 on the wafer in situ within the plasma etching chamber. The CVD step 902 includes conformally depositing a conductive coating in openings of a hardmask overlying a dielectric material (e.g., an ONO stack including a plurality of oxide layers separated by nitride layers) using a deposition gas comprising a metal (e.g., tungsten). The conductive coating includes the metal from the deposition gas. The RIE step includes etching the dielectric material through the openings of the hardmask using plasma generated from an etch precursor gas comprising an etchant species to extend recesses into the dielectric material. The plasma includes reactive ions of the etchant species.

As before, the method 900 may also have various implementations chosen to suit a particular application. For example, a preliminary RIE step may be performed in situ within the plasma etching chamber before the CVD step. The preliminary RIE step may include etching the dielectric material through the openings of the hardmask using plasma generated from the etch precursor gas to extend the recesses into the dielectric material. Depositing the conductive coating during the deposition step may include a reduction reaction that reduces the oxidation state of the metal (e.g., tungsten) in the deposition gas. A nitrogen treatment step may be performed that includes forming a conformal intermediate layer comprising nitrogen in the openings of the hardmask and the CVD step may include conformally depositing the conductive coating (e.g., a tungsten coating) on the conformal intermediate layer.

The conductive coating may also include tungsten nitride or tungsten carbide, for example. In the case of tungsten nitride, the reduction reaction may include using a nitrogen-containing gas to reduce the tungsten and deposit the tungsten nitride. Similarly, in the case of tungsten carbide, the reduction reaction may include using a carbon-containing gas to reduce the tungsten and deposit the tungsten carbide. A modification step may also be included, such as a silane treatment to incorporate silicon at sidewalls of the recesses extending into the dielectric material. The silicon at the sidewalls may be used in a replacement reaction during the CVD step that includes replacing the silicon at the sidewalls of the recesses with the metal (e.g., tungsten) of the deposition gas.

The method 800 and the method 900 may be performed using a plasma etching system that includes a plasma etching chamber, a substrate support, an etch precursor gas source, a deposition gas source, and a controller. For example, the substrate support may be disposed in the plasma etching chamber and be configured to support a substrate comprising a dielectric material. The etch precursor gas source may be fluidically coupled to the plasma etching chamber and configured to supply an etch precursor gas through a first valve while the deposition gas source may be fluidically coupled to the plasma etching chamber and configured to supply a deposition gas comprising a metal through a second valve. Of course, other gas sources may also be included, such as modification gases, reductant gases, carrier gases, etc. Moreover, any of the gas sources may be implemented as a combination of several gas sources, such as if one of the gases is a mixture of gases or needs to be mixed in the plasma etching chamber rather than being stored together (e.g., in the case of reactive gases).

The controller may be operationally coupled to the first valve and the second valve and may include a processor and a non-transitory computer-readable medium storing a program including instructions that, when executed by the processor, perform a method such as the method 800 or the method 900. For example, the instructions may cause the processor to cyclically performing a cycle including an etch step and a deposition step in situ within the plasma etching chamber. In various implementations, the deposition step may be a CVD step and is a PE-CVD step in some implementations.

Example embodiments of the invention are summarized here. Other embodiments can also be understood from the entirety of the specification as well as the claims filed herein.

### Example 1

A method of etching a dielectric material, the method including cyclically performing a cycle including the following steps in situ within an etching chamber: performing an etch step including etching the dielectric material through openings of a mask using plasma generated from an etch precursor gas to form recesses in the dielectric material; and performing a deposition step including depositing a conductive coating including a metal on both the mask and the dielectric material including sidewalls of the recesses using a deposition gas including the metal.

### Example 2

The method of example 1, where the cycle further includes: performing a modification step including forming an intermediate layer at the sidewalls of the recesses after the etch step and before the deposition step, the deposition step including depositing the conductive coating on the intermediate layer.

### Example 3

The method of one of examples 1 and 2, where depositing the conductive coating during the deposition step includes a reduction reaction that reduces the oxidation state of the metal in the deposition gas to deposit the conductive coating.

### Example 4

The method of one of examples 1 and 2, where depositing the conductive coating during the deposition step includes a replacement reaction between a seed material at the sidewalls of the recesses and the metal of the deposition gas.

### Example 5

The method of example 4, where the seed material includes silicon, and where the metal is tungsten.

### Example 6

The method of one of examples 1 to 5, where depositing the conductive coating during the deposition step includes depositing the conductive coating on sidewalls of the mask and the sidewalls of the recesses so that the conductive coating extends from a top surface of the mask substantially to bottom surfaces of the recesses.

### Example 7.

The method of one of examples 1 to 6, where the mask is a conductive mask.

### Example 8

A method of high aspect ratio contact (HARC) etching a wafer within a plasma etching chamber using chemical vapor deposition (CVD) and reactive-ion etching (RIE), the method including: performing a CVD step on the wafer in situ within the plasma etching chamber, the CVD step including conformally depositing a conductive coating in openings of a hardmask overlying a dielectric material using a deposition gas including a metal, the conductive coating including the metal; and performing an RIE step on the wafer in situ within the plasma etching chamber, the RIE step including etching the dielectric material through the openings of the hardmask using plasma generated from an etch precursor gas including an etchant species to extend recesses into the dielectric material, the plasma including reactive ions of the etchant species.

### Example 9

The method of example 8, where the dielectric material is an ONO stack including a plurality of oxide layers separated by nitride layers.

### Example 10

The method of one of examples 8 and 9, further including: performing a preliminary RIE step in situ within the plasma etching chamber before the CVD step, the preliminary RIE step including etching the dielectric material through the openings of the hardmask using plasma generated from the etch precursor gas to extend the recesses into the dielectric material.

### Example 11

The method of one of examples 8 to 10, where the metal is tungsten, and where depositing the conductive coating during the deposition step includes a reduction reaction that reduces the oxidation state of the tungsten in the deposition gas.

### Example 12

The method of example 11, further including: performing a nitrogen treatment step including forming a conformal intermediate layer including nitrogen in the openings of the hardmask, where the CVD step includes conformally depositing the conductive coating on the conformal intermediate layer, the conductive coating being a tungsten coating.

### Example 13

The method of one of examples 11 and 12, where the conductive coating includes tungsten nitride, and where the reduction reaction includes using a nitrogen-containing gas to reduce the tungsten and deposit the tungsten nitride.

### Example 14

The method of example 11, where the conductive coating includes tungsten carbide, and where the reduction reaction includes using a carbon-containing gas to reduce the tungsten and deposit the tungsten carbide.

### Example 15

The method of one of examples 8 to 11, where the metal is tungsten, the method further including: performing a modification step including a silane treatment to incorporate silicon at sidewalls of the recesses extending into the dielectric material, where conformally depositing the conductive coating during the CVD step includes a replacement reaction replacing the silicon at the sidewalls of the recesses with the tungsten of the deposition gas.

### Example 16

A plasma etching system including: a plasma etching chamber; a substrate support disposed in the plasma etching chamber and configured to support a substrate including a dielectric material; an etch precursor gas source fluidically coupled to the plasma etching chamber and configured to supply an etch precursor gas through a first valve; a deposition gas source fluidically coupled to the plasma etching chamber and configured to supply a deposition gas including a metal through a second valve; and a controller operationally coupled to the first valve and the second valve, the controller including a processor and a non-transitory computer-readable medium storing a program including instructions that, when executed by the processor, perform a method including cyclically performing a cycle including the following steps in situ within the plasma etching chamber: performing an etch step including etching the dielectric material through openings of a mask using plasma generated from the etch precursor gas to form recesses in the dielectric material; and performing a deposition step including depositing a conductive coating including the metal on both the mask and the dielectric material including sidewalls of the recesses using the deposition gas.

### Example 17

The plasma etching system of example 16, where the deposition step includes plasma-enhanced chemical vapor deposition (PE-CVD).

### Example 18

The plasma etching system of one of examples 16 and 17, where the cycle further includes: performing a modification step including forming an intermediate layer at the sidewalls of the recesses after the etch step and before the deposition step, where the deposition step includes depositing the conductive coating on the intermediate layer.

### Example 19

The plasma etching system of one of examples 16 to 18, where depositing the conductive coating during the deposition step includes a reduction reaction that reduces the oxidation state of the metal in the deposition gas to deposit the conductive coating.

### Example 20

The plasma etching system of one of examples 16 to 19, where depositing the conductive coating during the deposition step includes a replacement reaction replacing a seed material at the sidewalls of the recesses with the metal of the deposition gas.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of etching a dielectric material, the method comprising cyclically performing a cycle comprising the following steps in situ within an etching chamber:
performing an etch step comprising etching the dielectric material through openings of a mask using plasma generated from an etch precursor gas to form recesses in the dielectric material; and
performing a deposition step comprising depositing a conductive coating comprising a metal on both the mask and the dielectric material including sidewalls of the recesses using a deposition gas comprising the metal.

2. The method of claim 1, wherein the cycle further comprises:
performing a modification step comprising forming an intermediate layer at the sidewalls of the recesses after the etch step and before the deposition step, the deposition step comprising depositing the conductive coating on the intermediate layer.

3. The method of claim 1, wherein depositing the conductive coating during the deposition step comprises a reduction reaction that reduces the oxidation state of the metal in the deposition gas to deposit the conductive coating.

4. The method of claim 1, wherein depositing the conductive coating during the deposition step comprises a replacement reaction between a seed material at the sidewalls of the recesses and the metal of the deposition gas.

5. The method of claim 4, wherein the seed material comprises silicon, and wherein the metal is tungsten.

6. The method of claim 1, wherein depositing the conductive coating during the deposition step comprises depositing the conductive coating on sidewalls of the mask and the sidewalls of the recesses so that the conductive coating extends from a top surface of the mask substantially to bottom surfaces of the recesses.

7. The method of claim 1, wherein the mask is a conductive mask.

8. A method of high aspect ratio contact (HARC) etching a wafer within a plasma etching chamber using chemical vapor deposition (CVD) and reactive-ion etching (RIE), the method comprising:
performing a CVD step on the wafer in situ within the plasma etching chamber, the CVD step comprising conformally depositing a conductive coating in openings of a hardmask overlying a dielectric material using a deposition gas comprising a metal, the conductive coating comprising the metal; and
performing an RIE step on the wafer in situ within the plasma etching chamber, the RIE step comprising etching the dielectric material through the openings of the hardmask using plasma generated from an etch precursor gas comprising an etchant species to extend recesses into the dielectric material, the plasma comprising reactive ions of the etchant species.

9. The method of claim 8, wherein the dielectric material is an ONO stack comprising a plurality of oxide layers separated by nitride layers.

10. The method of claim 8, further comprising:
performing a preliminary RIE step in situ within the plasma etching chamber before the CVD step, the preliminary RIE step comprising etching the dielectric material through the openings of the hardmask using plasma generated from the etch precursor gas to extend the recesses into the dielectric material.

11. The method of claim 8, wherein the metal is tungsten, and wherein depositing the conductive coating during the deposition step comprises a reduction reaction that reduces the oxidation state of the tungsten in the deposition gas.

12. The method of claim 11, further comprising:
performing a nitrogen treatment step comprising forming a conformal intermediate layer comprising nitrogen in the openings of the hardmask, wherein the CVD step comprises conformally depositing the conductive coating on the conformal intermediate layer, the conductive coating being a tungsten coating.

13. The method of claim 11, wherein the conductive coating comprises tungsten nitride, and wherein the reduction reaction comprises using a nitrogen-containing gas to reduce the tungsten and deposit the tungsten nitride.

14. The method of claim 11, wherein the conductive coating comprises tungsten carbide, and wherein the reduction reaction comprises using a carbon-containing gas to reduce the tungsten and deposit the tungsten carbide.

15. The method of claim 8, wherein the metal is tungsten, the method further comprising:
performing a modification step comprising a silane treatment to incorporate silicon at sidewalls of the recesses extending into the dielectric material, wherein conformally depositing the conductive coating during the CVD step comprises a replacement reaction replacing the silicon at the sidewalls of the recesses with the tungsten of the deposition gas.

16. A plasma etching system comprising:
a plasma etching chamber;
a substrate support disposed in the plasma etching chamber and configured to support a substrate comprising a dielectric material;
an etch precursor gas source fluidically coupled to the plasma etching chamber and configured to supply an etch precursor gas through a first valve;
a deposition gas source fluidically coupled to the plasma etching chamber and configured to supply a deposition gas comprising a metal through a second valve; and
a controller operationally coupled to the first valve and the second valve, the controller comprising a processor and a non-transitory computer-readable medium storing a program including instructions that, when executed by the processor, perform a method comprising cyclically performing a cycle comprising the following steps in situ within the plasma etching chamber:
performing an etch step comprising etching the dielectric material through openings of a mask using plasma generated from the etch precursor gas to form recesses in the dielectric material; and
performing a deposition step comprising depositing a conductive coating comprising the metal on both the mask and the dielectric material including sidewalls of the recesses using the deposition gas.

17. The plasma etching system of claim 16, wherein the deposition step comprises plasma-enhanced chemical vapor deposition (PE-CVD).

18. The plasma etching system of claim 16, wherein the cycle further comprises:
performing a modification step comprising forming an intermediate layer at the sidewalls of the recesses after the etch step and before the deposition step, wherein the deposition step comprises depositing the conductive coating on the intermediate layer.

19. The plasma etching system of claim 16, wherein depositing the conductive coating during the deposition step comprises a reduction reaction that reduces the oxidation state of the metal in the deposition gas to deposit the conductive coating.

20. The plasma etching system of claim 16, wherein depositing the conductive coating during the deposition step comprises a replacement reaction replacing a seed material at the sidewalls of the recesses with the metal of the deposition gas.
